(19) United States
(12) Patent Application Publication
(10) Pub. No.: US 2025/0132167 A1
(43) Pub. Date: Apr. 24, 2025

(54) FILM FORMING METHOD AND PROCESSING SYSTEM

(71) Applicant: Tokyo Electron Limited, Tokyo (JP)

(72) Inventors: Shinya OKABE, Nirasaki City (JP); Atsushi MATSUMOTO, Nirasaki City (JP); Toshiaki ARIMA, Nirasaki City (JP)

(21) Appl. No.: 18/923,921

(22) Filed: Oct. 23, 2024

(30) Foreign Application Priority Data
Oct. 24, 2023 (JP) 2023-182199
Sep. 17, 2024 (JP) 2024-159810

(51) Int. Cl. H01L 21/3205; C23C 16/52; H01L 21/02

(52) U.S. Cl. CPC H01L 21/32053; C23C 16/52; H01L 21/02381; H01L 21/02697

(57) ABSTRACT

A film forming method includes: (a) preparing a substrate having a doped region, which contains silicon with an added impurity, formed on a surface; (b) forming a diffusion prevention layer, which contains the impurity, on the doped region; and (c) forming a metal film on the doped region where the diffusion prevention layer is formed, and forming a metal silicide film by a reaction between the metal film and the silicon of the doped region, wherein (b) includes supplying an impurity-containing gas that contains the impurity to the substrate without converting the impurity-containing gas into a plasma.

### CROSS-REFERENCE TO RELATED APPLICATIONS

This application is based upon and claims the benefit of priority from Japanese Patent Application No. 2023-182199, filed on Oct. 24, 2023, and Japanese Patent Application No. 2024-159810, filed on Sep. 17, 2024, the entire contents of which are incorporated herein by reference.

### TECHNICAL FIELD

The present disclosure relates to a film forming method and a processing system.

### BACKGROUND

A technique is known in which a titanium-containing gas is supplied to a silicon wafer, a plasma is generated to form a titanium film, and a titanium silicide film is formed by a reaction between the titanium film and silicon of the silicon wafer (see, for example, Patent Documents 1 and 2).

### PRIOR ART DOCUMENTS

### Patent Documents

Patent Document 1: Japanese Laid-open Publication No. 2004-158828
Patent Document 2: Japanese Laid-open Publication No. 2003-203976

### SUMMARY

According to one embodiment of the present disclosure, a film forming method includes: (a) preparing a substrate having a doped region, which contains silicon with an added impurity, formed on a surface; (b) forming a diffusion prevention layer, which contains the impurity, on the doped region; and (c) forming a metal film on the doped region where the diffusion prevention layer is formed, and forming a metal silicide film by a reaction between the metal film and the silicon of the doped region, wherein (b) includes supplying an impurity-containing gas that contains the impurity to the substrate without converting the impurity-containing gas into a plasma.

### BRIEF DESCRIPTION OF DRAWINGS

The accompanying drawings, which are incorporated in and constitute a part of the specification, illustrate embodiments of the present disclosure, and together with the general description given above and the detailed description of the embodiments given below, serve to explain the principles of the present disclosure.

FIG. 1 is a flowchart illustrating a film forming method according to a first example of an embodiment.

FIGS. 2A to 2D are cross-sectional views illustrating the film forming method according to the first example of the embodiment.

FIG. 3 is a flowchart illustrating a film forming method according to a second example of the embodiment.

FIGS. 4A to 4D are cross-sectional views illustrating the film forming method according to the second example of the embodiment.

FIG. 5 is a flowchart illustrating a film forming method according to a third example of the embodiment.

FIG. 6 is a flowchart illustrating a film forming method according to a fourth example of the embodiment.

FIG. 7 is a diagram illustrating an example of a processing system according to the embodiment.

FIG. 8 is a diagram illustrating an example of a processing apparatus according to the embodiment.

FIG. 9 is a diagram illustrating measurement results of contact resistance in Example 1.

FIG. 10 is a diagram illustrating measurement results of contact resistance in Example 2.

### DETAILED DESCRIPTION

Reference will now be made in detail to various embodiments, examples of which are illustrated in the accompanying drawings. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

Hereinafter, non-limiting exemplary embodiments of the present disclosure are described with reference to the accompanying drawings. In all the accompanying drawings, the same or corresponding members or components are denoted by the same or corresponding reference numerals, and redundant descriptions thereof are omitted.

### [Film Forming Method]

A film forming method according to an embodiment is described. The film forming method according to the embodiment includes, before forming a metal silicide film on a doped region containing silicon (Si) with an added impurity, forming, on the doped region, a diffusion prevention layer containing the same impurity as the doped region. Hereinafter, a case where the impurity is boron (B) and the metal silicide film is a titanium silicide (TiSi) film is described by way of example.

### First Example

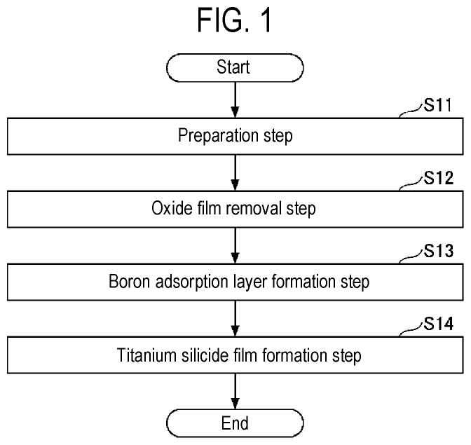

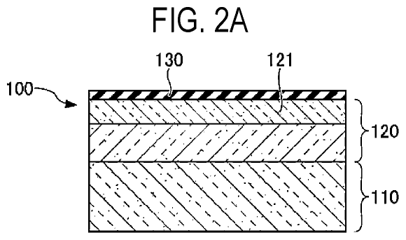

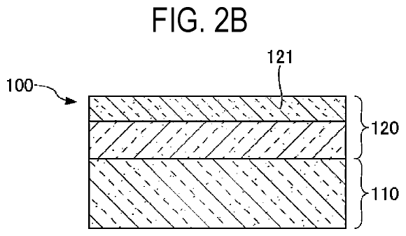

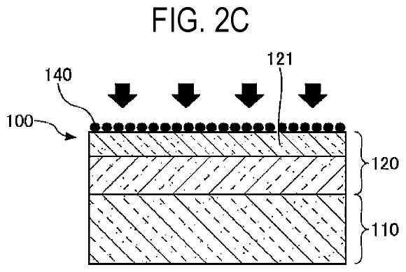

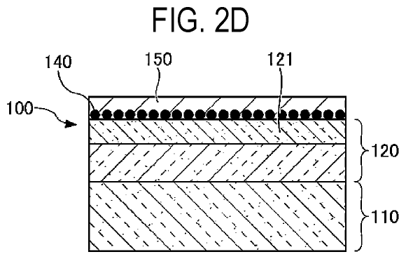

A film forming method according to a first example of the embodiment is described with reference to FIGS. 1 and 2A to 2D. FIG. 1 is a flowchart illustrating the film forming method according to the first example of the embodiment. FIGS. 2A to 2D are cross-sectional views illustrating the film forming method according to the first example of the embodiment.

The film forming method according to the first example of the embodiment includes forming a boron adsorption layer 140 as the diffusion prevention layer. As illustrated in FIG. 1, the film forming method according to the first example of the embodiment includes a preparation step S11, an oxide film removal step S12, a boron adsorption layer formation step S13, and a titanium silicide film formation step S14.

The preparation step S11 includes preparing a substrate 100, as illustrated in FIG. 2A. The substrate 100 includes a silicon single crystal substrate 110 and a silicon epitaxial layer 120 on the silicon single crystal substrate 110. The silicon epitaxial layer 120 includes a doped region 121 with added boron. The doped region 121 constitutes a surface of the silicon epitaxial layer 120. The doped region 121 is, for example, a region exposed from a contact hole formed at an insulating film. A native oxide film 130 may be present on a surface of the doped region 121.

The oxide film removal step S12 is performed after the preparation step S11. The oxide film removal step S12 includes removing the native oxide film 130 on the surface of the doped region 121, as illustrated in FIG. 2B. The oxide film removal step S12 includes, for example, a chemical oxide removal (COR) processing and a post heat treatment (PHT) processing. The COR processing includes supplying a gas containing a halogen element and a basic gas as process gases to the substrate 100, thereby causing a chemical reaction between the native oxide film 130 on the surface of the doped region 121 and the process gases to produce a reaction product. The gas containing a halogen element is, for example, a hydrogen fluoride (HF) gas. The basic gas is, for example, an ammonia (NH₃) gas. In this case, the reaction product mainly includes ammonium silicofluoride [(NH₄)₂SiF₆] or water (H₂O). The PHT processing includes heating the reaction product produced by the COR processing and sublimating the reaction product such as ammonium silicofluoride, etc. The oxide film removal step S12 is not limited to the step including the COR processing and PHT processing. For example, the oxide film removal step S12 may not include the PHT processing. When there is no native oxide film 130 on the surface of the doped region 121, the oxide film removal step S12 may be omitted.

The boron adsorption layer formation step S13 is performed after the oxide film removal step S12. The boron adsorption layer formation step S13 includes forming the boron adsorption layer 140 on the doped region 121 by supplying a diborane (B₂H₆) gas to the substrate 100 without converting the diborane gas into a plasma, as illustrated in FIG. 2C. The boron adsorption layer formation step S13 may be performed without supplying a metal-containing gas to the substrate 100. The diborane gas is, for example, continuously supplied to the substrate 100. The diborane gas may be supplied intermittently to the substrate 100. The boron adsorption layer formation step S13 may include supplying a carrier gas along with the diborane gas to the substrate 100. The carrier gas is, for example, an inert gas such as a nitrogen (N₂) gas or argon (Ar). The boron adsorption layer formation step S13 includes maintaining the substrate 100 at a first temperature. The first temperature is, for example, 150 degrees C. or higher. In this case, boron is likely to adsorb on the doped region 121. The first temperature is, for example, a temperature lower than a temperature at which the diborane gas self-decomposes. In this case, the self-decomposition of the diborane gas is prevented, which prevents deposition of boron on various regions inside the processing container. As a result, it is possible to prevent generation of particles. The temperature at which the diborane gas self-decomposes is approximately 300 degrees C.

The titanium silicide film formation step S14 is performed after the boron adsorption layer formation step S13. The titanium silicide film formation step S14 includes forming a titanium (Ti) film on the doped region 121 where the boron adsorption layer is formed, and forming a titanium silicide film 150 by a reaction between the titanium film and silicon of the doped region 121, as illustrated in FIG. 2D. The titanium silicide film formation step S14 includes exposing the substrate 100 to a titanium tetrachloride (TiCl₄) gas (second metal-containing gas) and a plasma generated from a reducing gas so as to form the titanium film on the doped region 121. The titanium silicide film formation step S14 may also include alternately repeating the supply of the titanium tetrachloride gas to the substrate 100 and the supply of the reducing gas formed into a plasma to the substrate 100 so as to form the titanium film on the doped region 121. The titanium silicide film formation step S14 may also include simultaneously performing the supply of the titanium tetrachloride gas to the substrate 100 and the supply of the reducing gas formed into a plasma to the substrate 100 to form the titanium film on the doped region 121. The titanium film reacts with the silicon of the doped region 121 to form the titanium silicide film 150. The reducing gas is, for example, a hydrogen (H₂) gas. The titanium silicide film formation step S14 includes maintaining the substrate 100 at a second temperature. The second temperature is, for example, higher than the first temperature. The second temperature is, for example, 380 degrees C. or higher and 450 degree C. or lower. By forming the titanium film at the second temperature, a thermal reaction between the titanium film and the silicon of the doped region 121 may form the titanium silicide film 150 while the titanium film is being formed.

According to the film forming method of the first example of the embodiment described above, the boron adsorption layer 140 is formed on the doped region 121 before forming the titanium silicide film 150 on the doped region 121. In this case, when forming the titanium silicide film 150, boron of the boron adsorption layer 140 is more likely to diffuse into the titanium silicide film 150 than boron of the doped region 121. Therefore, the diffusion of the boron from the doped region 121 to the titanium silicide film 150 is prevented, which allows the doped region 121 to be maintained at a high boron concentration. As a result, an increase in contact resistance between the doped region 121 and the titanium silicide film 150 is prevented, achieving a low contact resistance.

According to the film forming method of the first example of the embodiment, the boron adsorption layer 140 is formed as the diffusion prevention layer. In this case, it is possible to prevent elements other than boron from being introduced as impurities into the doped region 121.

### Second Example

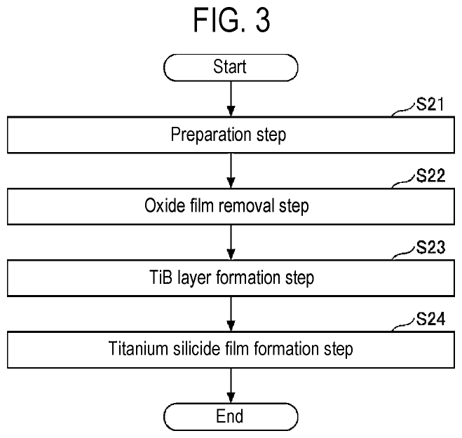

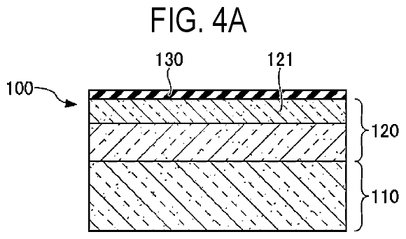

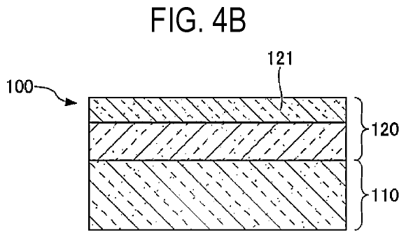

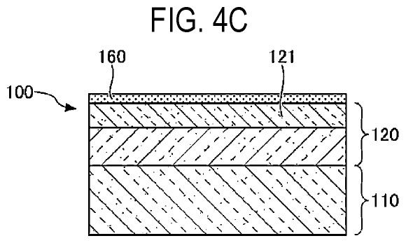

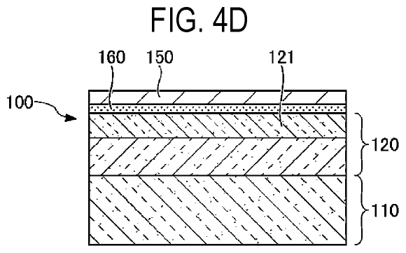

A film forming method according to a second example of the embodiment is described with reference to FIGS. 3 and 4A to 4D. FIG. 3 is a flowchart illustrating the film forming method according to the second example of the embodiment. FIGS. 4A to 4D are cross-sectional views illustrating the film forming method according to the second example of the embodiment.

The film forming method according to the second example of the embodiment includes forming a TiB layer 160 as the diffusion prevention layer. As illustrated in FIG. 3, the film forming method according to the second example of the embodiment includes a preparation step S21, an oxide film removal step S22, a TiB layer formation step S23, and a titanium silicide film formation step S24.

The preparation step S21 includes preparing the substrate 100, as illustrated in FIG. 4A. The preparation step S21 may be the same as the preparation step S11.

The oxide film removal step S22 is performed after the preparation step S21. The oxide film removal step S22 includes removing the native oxide film 130 on the surface of the doped region 121, as illustrated in FIG. 4B. The oxide film removal step S22 may be the same as the oxide film removal step S12.

The TiB layer formation step S23 is performed after the oxide film removal step S22. The TiB layer formation step S23 includes forming the TiB layer 160 on the doped region 121 by supplying a diborane gas and titanium tetrachloride gas (first metal-containing gas) to the substrate 100, as illustrated in FIG. 4C. The TiB layer formation step S23 includes, for example, alternately repeating the supply of the diborane gas to the substrate 100 without converting the diborane gas into a plasma and the supply of the titanium tetrachloride gas to the substrate 100. In this case, the diborane gas may first be supplied to the substrate 100 without converting the diborane gas into a plasma. This aids to prevent chlorine (Cl) of the titanium tetrachloride gas from being introduced as an impurity into the doped region 121. The TiB layer formation step S23 may include simultaneously performing the supply of the diborane gas to the substrate 100 without converting the diborane gas into a plasma and the supply of the titanium tetrachloride gas to the substrate 100. The titanium tetrachloride gas may be supplied to the substrate 100 in a plasma state or without being formed into a plasma. The TiB layer formation step S23 includes maintaining the substrate 100 at a third temperature. The third temperature is, for example, 200 degrees C. or higher and 450 degree C. or lower.

The titanium silicide film formation step S24 is performed after the TiB layer formation step S23. The titanium silicide film formation step S24 includes forming a titanium film on the doped region 121 where the TiB layer 160 is formed, and forming the titanium silicide film 150 by a reaction between the titanium film and silicon of the doped region 121, as illustrated in FIG. 4D. The titanium silicide film formation step S24 may be the same as the titanium silicide film formation step S14.

According to the film forming method of the second example of the embodiment described above, the TiB layer 160 is formed on the doped region 121 before forming the titanium silicide film 150 on the doped region 121. In this case, when forming the titanium silicide film 150, boron of the TiB layer 160 is more likely to diffuse into the titanium silicide film 150 than boron of the doped region 121. Therefore, the diffusion of the boron from the doped region 121 to the titanium silicide film 150 is prevented, which allows the doped region 121 to be maintained at a high boron concentration. As a result, an increase in contact resistance between the doped region 121 and the titanium silicide film 150 is prevented, achieving a low contact resistance.

According to the film forming method of the second example of the embodiment, the TiB layer 160 is formed as the diffusion prevention layer. In this case, it is possible to effectively prevent the diffusion of the boron from the doped region 121 to the titanium silicide film 150.

### Third Example

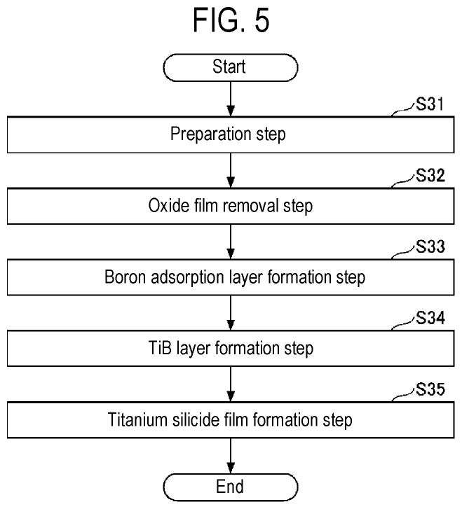

A film forming method according to a third example of the embodiment is described with reference to FIG. 5. FIG. 5 is a flowchart illustrating the film forming method according to the third example of the embodiment.

The film forming method according to the third example of the embodiment includes forming, as the diffusion prevention layer, the boron adsorption layer 140 and the TiB layer 160, in this order. As illustrated in FIG. 5, the film forming method according to the third example of the embodiment includes a preparation step S31, an oxide film removal step S32, a boron adsorption layer formation step S33, a TiB layer formation step S34, and a titanium silicide film formation step S35.

The preparation step S31 and the oxide film removal step S32 may be the same as the preparation step S11 and the oxide film removal step S12, respectively.

The boron adsorption layer formation step S33 is performed after the oxide film removal step S32. The boron adsorption layer formation step S33 may be the same as the boron adsorption layer formation step S13.

The TiB layer formation step S34 is performed after the boron adsorption layer formation step S33. The TiB layer formation step S34 may be the same as the TiB layer formation step S23.

The titanium silicide film formation step S35 is performed after the TiB layer formation step S34. The titanium silicide film formation step S35 may be the same as the titanium silicide film formation step S14.

According to the film forming method of the third example of the embodiment described above, the boron adsorption layer 140 and the TiB layer 160 are formed in this order on the doped region 121 before forming the titanium silicide film 150 on the doped region 121. In this case, when forming the titanium silicide film 150, boron of the boron adsorption layer 140 and boron of the TiB layer 160 are more likely to diffuse into the titanium silicide film 150 than boron of the doped region 121. Therefore, the diffusion of the boron from the doped region 121 to the titanium silicide film 150 is prevented, which allows the doped region 121 to be maintained at a high boron concentration. As a result, an increase in contact resistance between the doped region 121 and the titanium silicide film 150 is prevented, achieving a low contact resistance.

According to the film forming method of the third example of the embodiment, the boron adsorption layer 140 and the TiB layer 160 are formed as the diffusion prevention layer in this order. In this case, it is possible to effectively prevent the diffusion of the boron from the doped region 121 to the titanium silicide film 150 while preventing elements other than boron from being introduced as impurities into the doped region 121.

### Fourth Example

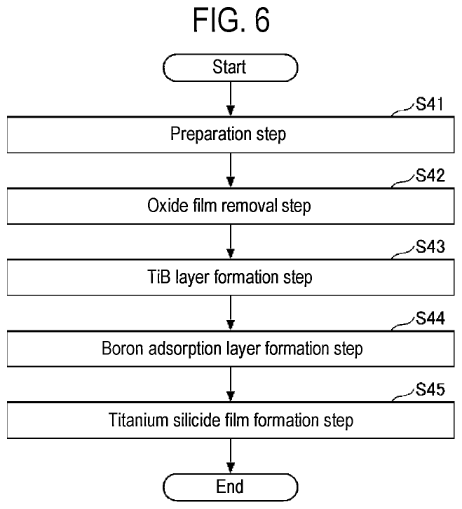

A film forming method according to a fourth example of the embodiment is described with reference to FIG. 6. FIG. 6 is a flowchart illustrating the film forming method according to the fourth example of the embodiment.

The film forming method according to the fourth example of the embodiment includes forming, as the diffusion prevention layer, the TiB layer 160 and the boron adsorption layer 140, in this order. As illustrated in FIG. 6, the film forming method according to the fourth example of the embodiment includes a preparation step S41, an oxide film removal step S42, a TiB layer formation step S43, a boron adsorption layer formation step S44, and a titanium silicide film formation step S45.

The preparation step S41 and the oxide film removal step S42 may be the same as the preparation step S11 and the oxide film removal step S12, respectively.

The TiB layer formation step S43 is performed after the oxide film removal step S42. The TiB layer formation step S43 may be the same as the TiB layer formation step S23.

The boron adsorption layer formation step S44 is performed after the TiB layer formation step S43. The boron adsorption layer formation step S44 may be the same as the boron adsorption layer formation step S13.

The titanium silicide film formation step S45 is performed after the boron adsorption layer formation step S44. The titanium silicide film formation step S45 may be the same as the titanium silicide film formation step S14.

According to the film forming method of the fourth example of the embodiment described above, the TiB layer 160 and the boron adsorption layer 140 are formed in this order on the doped region 121 before forming the titanium silicide film 150 on the doped region 121. In this case, when forming the titanium silicide film 150, boron of the TiB layer 160 and boron of the boron adsorption layer 140 are more likely to diffuse into the titanium silicide film 150 than boron of the doped region 121. Therefore, the diffusion of the boron from the doped region 121 to the titanium silicide film 150 is prevented, which allows the doped region 121 to be maintained at a high boron concentration. As a result, an increase in contact resistance between the doped region 121 and the titanium silicide film 150 is prevented, achieving a low contact resistance.

### [Processing System]

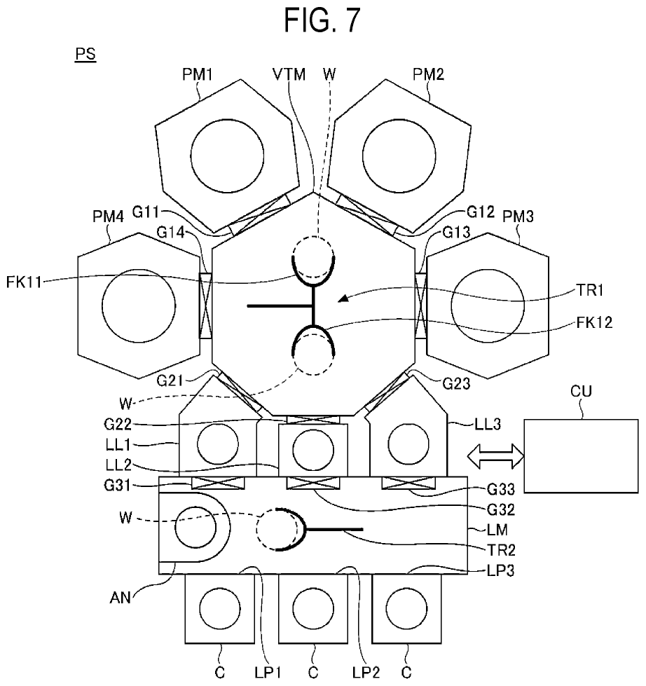

An example of a processing system PS capable of carrying out the film forming methods according to the first to fourth examples of the embodiment is described with reference to FIG. 7. FIG. 7 is a diagram illustrating an example of the processing system PS according to the embodiment.

The processing system PS includes processing apparatuses PM1 to PM4, a vacuum transfer chamber VTM, load lock chambers LL1 to LL3, an atmospheric transfer chamber LM, load ports LP1 to LP3, and an overall controller CU.

The processing apparatuses PM1 to PM4 are connected to the vacuum transfer chamber VTM via gate valves G11 to G14, respectively. Each of the interiors of the processing apparatuses PM1 to PM4 is depressurized to a predetermined vacuum atmosphere. Each of the processing apparatuses PM1 to PM4 performs a desired processing on the substrate W in the interior thereof. The processing apparatus PM1 is, for example, an apparatus that performs a COR processing of the oxide film removal steps S12, S22, S32, and S42. The processing apparatus PM2 is, for example, an apparatus that performs a PHT processing of the oxide film removal steps S12, S22, S32, and S42. The processing apparatus PM3 is an apparatus that performs, for example, the boron adsorption layer formation steps S13, S33, and S44 and the TiB layer formation steps S23, S34, and S43. The processing apparatus PM4 is an apparatus that performs, for example, the titanium silicide film formation steps S14, S24, S35, and S45.

An interior of the vacuum transfer chamber VTM is depressurized to a predetermined vacuum atmosphere. A transfer mechanism TR1 is provided in the interior of the vacuum transfer chamber VTM. The transfer mechanism TR1 is configured to be capable of transferring the substrate W in a depressurized state. The transfer mechanism TR1 transfers the substrate W to and from the processing apparatuses PM1 to PM4 and the load lock chambers LL1 to LL3. The transfer mechanism TR1 includes, for example, two independently movable forks FK11 and FK12. Each of the forks FK11 and FK12 is configured to be capable of holding the substrate W.

The load lock chambers LL1 to LL3 are connected to the vacuum transfer chamber VTM via gate valves G21 to G23, respectively. The load lock chambers LL1 to LL3 are connected to the atmospheric transfer chamber LM via gate valves G31 to G33, respectively. Interiors of the load lock chambers LL1 to LL3 are switchable between an atmospheric atmosphere and a vacuum atmosphere.

An interior of the atmospheric transfer chamber LM has an atmospheric atmosphere. For example, a downflow of clean air is formed inside the atmospheric transfer chamber LM. An aligner AN is provided in the interior of the atmospheric transfer chamber LM. The aligner AN performs alignment of the substrate W. A transfer mechanism TR2 is provided in the atmospheric transfer chamber LM. The transfer mechanism TR2 transfers the substrate W to and from the load lock chambers LL1 to LL3, carriers C of the load ports LP1 to LP3, and the aligner AN.

The load ports LP1 to LP3 are provided on a long side wall surface of the atmospheric transfer chamber LM. The load ports LP1 to LP3 are installed with the carriers C, respectively. The carrier C is, for example, a front opening unified pod (FOUP).

The overall controller CU is, for example, a computer. The overall controller CU includes a central processing unit (CPU), a random access memory (RAM), a read only memory (ROM), and an auxiliary storage device. The CPU operates based on programs stored in the ROM or the auxiliary storage device to control each component of the processing system PS. For example, the overall controller CU executes operations such as the operation of the processing apparatuses PM1 to PM4, the operation of the transfer mechanisms TR1 and TR2, the opening and closing of the gate valves G11 to G14, G21 to G23, and G31 to G33, and the switching of the atmosphere in the load lock chambers LL1 to LL3.

### [Operation of Processing System]

An example of the operation of the processing system PS according to the embodiment is described with reference to FIG. 7. Hereinafter, a case where the processing system PS performs the film forming method according to the first example of the embodiment is described by way of example. The same applies to cases where the processing system PS performs the film forming methods according to the second to fourth examples of the embodiment. The operation of the processing system PS according to the embodiment is performed under the control of the overall controller CU.

First, the carrier C accommodating a plurality of substrates W therein is installed to the load port LP1. Each substrate W may be the substrate 100 with the doped region 121 formed on the surface.

Subsequently, the transfer mechanism TR2 transfers the substrate W accommodated in the carrier C to the aligner AN. Subsequently, the aligner AN aligns the substrate W. Next, the overall controller CU switches the gate valve G31 from a closed state to an open state. Subsequently, the transfer mechanism TR2 receives the substrate W from the aligner AN and transfers it to the load lock chamber LL1 having an atmospheric atmosphere. Next, the overall controller CU switches the gate valve G31 from the open state to the closed state. Next, the overall controller CU switches the interior of the load lock chamber LL1 from an atmospheric atmosphere to a vacuum atmosphere.

Next, the overall controller CU switches the gate valves G11 and G21 from the closed state to the open state. Subsequently, the transfer mechanism TR1 receives the substrate W from the load lock chamber LL1 and transfers it to the processing apparatus PM1. Next, the overall controller CU switches the gate valves G11 and G21 from the open state to the closed state.

Subsequently, the processing apparatus PM1 performs the COR processing of the oxide film removal step S12. Consequently, a surface layer of the native oxide film 130 on the surface of the doped region 121 formed on the surface of the substrate W is modified into a reaction product.

Next, the overall controller CU switches the gate valves G11 and G12 from the closed state to the open state. Subsequently, the transfer mechanism TR1 receives the substrate W from the processing apparatus PM1 and transfers it to the processing apparatus PM2. Next, the overall controller CU switches the gate valves G11 and G12 from the open state to the closed state.

Subsequently, the processing apparatus PM2 performs the PHT processing of the oxide film removal step S12. Consequently, the reaction product remaining on the surface of the substrate W is sublimated, enabling the removal of the native oxide film 130 on the surface of the doped region 121.

Next, the overall controller CU switches the gate valves G12 and G13 from the closed state to the open state. Subsequently, the transfer mechanism TR1 receives the substrate W from the processing apparatus PM2 and transfers it to the processing apparatus PM3. Next, the overall controller CU switches the gate valves G12 and G13 from the open state to the closed state.

Subsequently, the processing apparatus PM3 performs the boron adsorption layer formation step S13. Consequently, the boron adsorption layer 140 is formed on the doped region 121.

Next, the overall controller CU switches the gate valves G13 and G14 from the closed state to the open state. Subsequently, the transfer mechanism TR1 receives the substrate W from the processing apparatus PM3 and transfers it to the processing apparatus PM4. Next, the overall controller CU switches the gate valves G13 and G14 from the open state to the closed state.

Subsequently, the processing apparatus PM4 performs the titanium silicide film formation step S14. Consequently, a titanium film is formed on the boron adsorption layer 140 formed on the doped region 121. The titanium film reacts with silicon of the doped region 121 to form the titanium silicide film 150.

Next, the overall controller CU switches the gate valves G14 and G23 from the closed state to the open state. Subsequently, the transfer mechanism TR1 receives the substrate W from the processing apparatus PM4 and transfers it to the load lock chamber LL3 in a vacuum atmosphere. Next, the overall controller CU switches the gate valves G14 and G23 from the open state to the closed state. Next, the overall controller CU switches the interior of the load lock chamber LL3 from a vacuum atmosphere to an atmospheric atmosphere.

Next, the overall controller CU switches the gate valve G33 from the closed state to the open state. Subsequently, the transfer mechanism TR2 receives the substrate W from the load lock chamber LL3, transfers it to the carrier C installed at the load port LP3, and accommodates the substrate W in the carrier C. With the above, the processing for one substrate W is completed.

In the operation of the processing system PS described above, a case where the substrate W is transferred from the atmospheric transfer chamber LM to the vacuum transfer chamber VTM by way of the load lock chamber LL1, and the substrate W is transferred from the vacuum transfer chamber VTM to the atmospheric transfer chamber LM by way of the load lock chamber LL3 has been described. However, a transfer path for the substrate W is not limited to this. The substrate W may be transferred from the atmospheric transfer chamber LM to the vacuum transfer chamber VTM by way of any of the load lock chambers LL1 to LL3. The substrate W may be transferred from the vacuum transfer chamber VTM to the atmospheric transfer chamber LM by way of any of the load lock chambers LL1 to LL3.

### [Processing Apparatus]

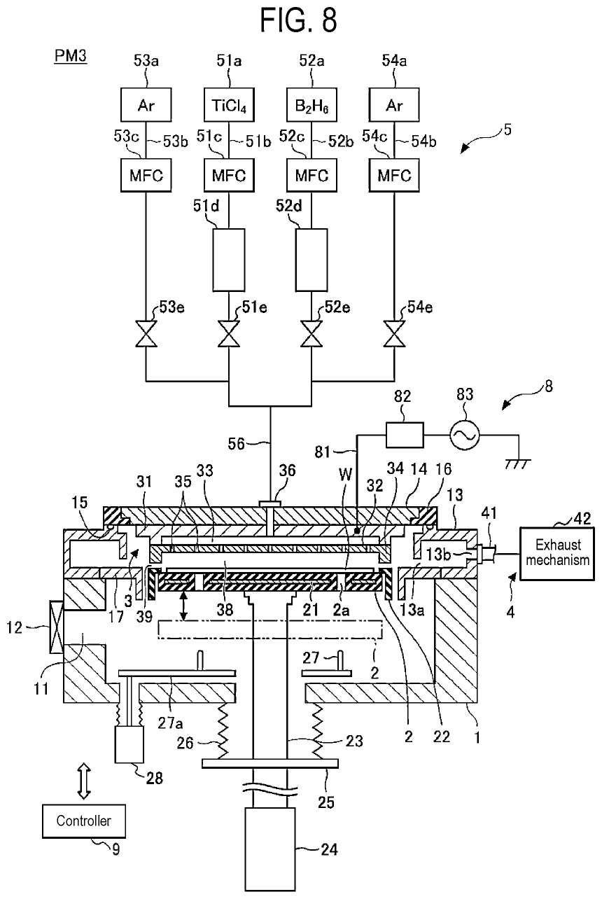

An example of the processing apparatus PM3 is described with reference to FIG. 8. FIG. 8 is a diagram illustrating an example of the processing apparatus PM3. The processing apparatus PM3 is configured to be capable of performing the boron adsorption layer formation steps S13, S33, and S44 and the TiB layer formation steps S23, S34, and S43.

As illustrated in FIG. 8, the processing apparatus PM3 includes a processing container 1, a stage 2, a shower head 3, an exhauster 4, a gas supplier 5, an RF power supplier 8, and a controller 9.

The processing container 1 is made of a metal such as aluminum and has a substantially cylindrical shape. The processing container 1 accommodates the substrate W therein. A loading/unloading port 11 for loading or unloading the substrate W is provided at a sidewall of the processing container 1. The loading/unloading port 11 is opened or closed by a gate valve 12. An annular exhaust duct 13 having a rectangular cross section is provided on a main body of the processing container 1. A slit 13a is formed at the exhaust duct 13 along an inner peripheral surface thereof. An exhaust port 13b is formed at an outer wall of the exhaust duct 13. A ceiling wall 14 is provided at an upper surface of the exhaust duct 13 to close an upper opening of the processing container 1 via an insulator member 16 interposed therebetween. A space between the exhaust duct 13 and the insulator member 16 is airtightly sealed with a seal ring 15. A dividing member 17 vertically divides the interior of the processing container 1 when the stage 2 and a cover member 22 are moved up to a processing position to be described later.

The stage 2 horizontally supports the substrate W inside the processing container 1. The stage 2 is formed in a shape of a disk slightly larger than the substrate W. The stage 2 is made of a ceramic material such as AlN or a metal material such as aluminum or nickel alloy. A heater 21 for heating the substrate W is embedded inside the stage 2. The heater 21 generates heat upon receiving power from a heater power supply (not illustrated). The substrate W is controlled to a predetermined temperature by controlling an output of the heater 21 according to a temperature signal from a thermocouple (not illustrated) provided near an upper surface of the stage 2. The cover member 22 is provided at the stage 2 to cover an outer peripheral region of the upper surface and a side surface. The cover member 22 is made of ceramics such as alumina.

A supporting member 23 is connected to a bottom surface of the stage 2. The supporting member 23 supports the stage 2. The supporting member 23 passes through a hole formed in a bottom wall of the processing container 1 from a center of the bottom surface of the stage 2, and extends downward from the processing container 1. A lower end of the supporting member 23 is connected to a lift 24. The stage 2 is moved up and down by the lift 24 via the supporting member 23. The stage 2 is moved up and down between the processing position indicated by a solid line in FIG. 8 and a transfer position indicated by a two-dot dashed line below the processing position. The processing position is a position where a processing is performed on the substrate W. The transfer position is a position where loading or unloading of the substrate W is performed. A flange 25 is installed at the supporting member 23 below the processing container 1. A bellows 26 is provided between a bottom surface of the processing container 1 and the flange 25. The bellows 26 separates the atmosphere inside the processing container 1 from the outside air, and expands or contracts in conjunction with the up-and-down movement of the stage 2.

Three (only two are illustrated) lifting pins 27 are provided near the bottom surface of the processing container 1. The lifting pins 27 protrude upward from a lifting plate 27a. The lifting pins 27 are moved up and down by a lift 28 provided below the processing container 1 via the lifting plate 27a. The lifting pins 27 are inserted through through-holes 2a provided in the stage 2 which is at the transfer position, thus being capable of protruding and retracting relative to the upper surface of the stage 2. The substrate W is transferred between a transfer mechanism (not illustrated) and the stage 2 by moving the lifting pins 27 up and down.

The shower head 3 supplies a process gas into the processing container 1 in a shower-like manner. The shower head 3 is made of a metal. The shower head 3 is provided to face the stage 2. The shower head 3 has substantially the same diameter as the stage 2. The shower head 3 includes a main body 31 fixed to a ceiling wall 14 of the processing container 1 and a shower plate 32 connected below the main body 31. A gas diffusion space 33 is formed between the main body 31 and the shower plate 32. A gas introduction hole 36 is provided at the gas diffusion space 33 to centrally penetrate both the ceiling wall 14 of the processing container 1 and the main body 31. An annular protrusion 34 is formed on a periphery of the shower plate 32 to protrude downward. A plurality of gas discharge holes 35 are formed at an inner flat surface of the annular protrusion 34. In a state where the stage 2 is present at the processing position, a processing space 38 is created between the stage 2 and the shower plate 32, and an upper surface of the cover member 22 and the annular protrusion 34 become close to each other to create an annular gap 39.

The exhauster 4 is used to exhaust the interior of the processing container 1. The exhauster 4 includes an exhaust pipe 41 and an exhaust mechanism 42. The exhaust pipe 41 is connected to the exhaust port 13b. The exhaust mechanism 42 includes a vacuum pump, a pressure control valve, and others, which are connected to the exhaust pipe 41. During a processing, a gas inside the processing container 1 reaches the exhaust duct 13 through the slit 13a, and is exhausted from the exhaust duct 13 through the exhaust pipe 41 by the exhaust mechanism 42.

The gas supplier 5 supplies a process gas into the processing container 1. The gas supplier 5 includes a titanium-containing gas source 51a, a boron-containing gas source 52a, an Ar gas source 53a, and an Ar gas source 54a.

The titanium-containing gas source 51a supplies a titanium-containing gas into the processing container 1 through a gas supply line 51b. The titanium-containing gas is used when forming the TiB layer 160. In the present embodiment, the titanium-containing gas is a titanium tetrachloride gas. A flow rate controller 51c, a storage tank 51d, and a valve 51e are interposed at the gas supply line 51b from an upstream. A downstream of the valve 51e of the gas supply line 51b is connected to the gas introduction hole 36 through a gas supply line 56. The titanium-containing gas supplied from the titanium-containing gas source 51a is temporarily stored in the storage tank 51d before being supplied into the processing container 1, and then supplied into the processing container 1 after being pressurized to a predetermined pressure inside the storage tank 51d. The supply and stoppage of the titanium-containing gas from the storage tank 51d to the processing container 1 are performed by opening and closing the valve 51e. By temporarily storing the titanium-containing gas in the storage tank 51d, a relatively large flow rate of the titanium-containing gas may be stably supplied into the processing container 1.

The boron-containing gas source 52a supplies a boron-containing gas into the processing container 1 through a gas supply line 52b. The boron-containing gas is used when forming the boron adsorption layer 140 and the TiB layer 160. In the present embodiment, the boron-containing gas is a diborane gas. A flow rate controller 52c, a storage tank 52d, and a valve 52e are interposed at the gas supply line 52b from an upstream. A downstream of the valve 52e of the gas supply line 52b is connected to the gas introduction hole 36 through the gas supply line 56. The boron-containing gas supplied from the boron-containing gas source 52a is temporarily stored in the storage tank 52d before being supplied into the processing container 1, and is then supplied into the processing container 1 after being pressurized to a predetermined pressure inside the storage tank 52d. The supply and stoppage of the boron-containing gas from the storage tank 52d to the processing container 1 are performed by opening and closing the valve 52e. By temporarily storing the boron-containing gas in the storage tank 52d, a relatively large flow rate of the boron-containing gas may be stably supplied into the processing container 1.

The Ar gas source 53a supplies an Ar gas as an inert gas into the processing container 1 through a gas supply line 53b. A flow rate controller 53c and a valve 53e are interposed at the gas supply line 53b from an upstream. A downstream of the valve 53e of the gas supply line 53b is connected to the gas supply line 51b. The Ar gas supplied from the Ar gas source 53a is supplied into the processing container 1. The supply and stoppage of the Ar gas to the processing container 1 are performed by opening and closing the valve 53e.

The Ar gas source 54a supplies an Ar gas as an inert gas into the processing container 1 through a gas supply line 54b. A flow rate controller 54c and a valve 54e are interposed at the gas supply line 54b from an upstream. A downstream of the valve 54e of the gas supply line 54b is connected to the gas supply line 52b. The Ar gas supplied from the Ar gas source 54a is supplied into the processing container 1. The supply and stoppage of the Ar gas to the processing container 1 are performed by opening and closing the valve 54e.

The processing apparatus PM3 is a capacitively coupled plasma apparatus. The stage 2 serves as a lower electrode, and the shower head 3 serves as an upper electrode. The stage 2 serving as the lower electrode is grounded via a condenser (not illustrated).

The shower head 3 serving as the upper electrode is supplied with radio frequency power (hereinafter also referred to as “RF power”) by the RF power supplier 8. The RF power supplier 8 includes a feed line 81, a matcher 82, and a radio frequency power supply 83. The radio frequency power supply 83 is a power supply that generates radio frequency power. The radio frequency power has a frequency suitable for plasma generation. The frequency of the radio frequency power ranges from 450 KHz to 100 MHz, for example. The radio frequency power supply 83 is connected to the main body 31 of the shower head 3 via the matcher 82 and the feed line 81. The matcher 82 includes a circuit for matching an output reactance of the radio frequency power supply 83 and a reactance of a load (upper electrode). The RF power supplier 8 has been described as supplying a radio frequency power to the shower head 3 serving as the upper electrode, but is not limited to this. It may be configured to supply radio frequency power to the stage 2 serving as the lower electrode.

The controller 9 is, for example, a computer. The controller 9 includes a central processing unit (CPU), a random access memory (RAM), a read only memory (ROM), an auxiliary storage device, and the like. The CPU operates based on programs stored in the ROM or the auxiliary storage device, and controls the operation of the processing apparatus PM3. The controller 9 may be provided inside or outside the processing apparatus PM3. If the controller 9 is provided outside the processing apparatus PM3, the controller 9 controls the processing apparatus PM3 via a wired or wireless communication device.

### [Operation of Processing Apparatus]

Referring to FIG. 8, a case where the processing apparatus PM3 performs the boron adsorption layer formation step S13 on the substrate W is described as an example of the operation of the processing apparatus PM3. The substrate W may be the substrate 100 with the doped region 121 formed on the surface.

First, the controller 9 opens the gate valve 12, transfers the substrate 100 into the processing container 1 by a transfer mechanism (not illustrated), and places the substrate 100 on the stage 2. The controller 9 closes the gate valve 12 after retracting the transfer mechanism from the interior of the processing container 1. Subsequently, the controller 9 heats the substrate 100 to a predetermined temperature by the heater 21 of the stage 2, and adjusts the interior of the processing container 1 to a predetermined pressure by the exhaust mechanism 42. The predetermined temperature and predetermined pressure may be the temperature and pressure used during the boron adsorption layer formation step S13, respectively.

Subsequently, the controller 9 controls each component of the processing apparatus PM3 to perform the boron adsorption layer formation step S13. Specifically, the controller 9 switches the valve 52e from a closed state to an open state. Consequently, a diborane gas is supplied to the substrate 100, forming the boron adsorption layer 140 on the doped region 121. After a predetermined time has passed, the controller 9 switches the valve 52e from the open state to the closed state.

Subsequently, the controller 9 unloads the substrate 100 from the interior of the processing container 1 in a reverse order from loading the substrate 100 into the processing container 1. With the above, the processing for one substrate 100 is completed.

Referring to FIG. 8, a case where the processing apparatus PM3 performs the TiB layer formation step S23 on the substrate W is described as another example of the operation of the processing apparatus PM3. The substrate W may be the substrate 100 with the doped region 121 formed on the surface.

First, the controller 9 opens the gate valve 12, transfers the substrate 100 into the processing container 1 by a transfer mechanism (not illustrated), and places the substrate 100 on the stage 2. The substrate 100 may be the substrate 100 with the doped region 121 formed on the surface. The controller 9 closes the gate valve 12 after retracting the transfer mechanism from the interior of the processing container 1. Subsequently, the controller 9 heats the substrate 100 to a predetermined temperature by the heater 21 of the stage 2, and adjusts the interior of the processing container 1 to a predetermined pressure by the exhaust mechanism 42. The predetermined temperature and predetermined pressure may be the temperature and pressure used during the TiB layer formation step S23, respectively.

Subsequently, the controller 9 controls each component of the processing apparatus PM3 to perform the TiB layer formation step S23. Specifically, the controller 9 switches the valve 52e from the closed state to the open state. Consequently, a diborane gas is supplied to the substrate 100 and adsorbs on the doped region 121. After a predetermined time has passed, the controller 9 switches the valve 52e from the open state to the closed state. Subsequently, the controller 9 switches the valve 51e from the closed state to the open state. Consequently, a titanium tetrachloride gas is supplied to the substrate 100 and adsorbs on the doped region 121. After a predetermined time has passed, the controller 9 switches the valve 51e from the open state to the closed state. The controller 9 alternately repeats the switching of the valve 52e and the switching of the valve 51e. Consequently, the TiB layer 160 is formed on the doped region 121.

Subsequently, the controller 9 unloads the substrate 100 from the interior of the processing container 1 in the reverse order from loading the substrate 100 into the processing container 1. With the above, the processing for one substrate 100 is completed.

### Example 1

In Example 1, a contact resistance between the doped region 121 and the titanium silicide film 150 is compared for cases where the boron adsorption layer 140 is formed and is not formed on the doped region 121, before forming the titanium silicide film 150 on the doped region 121. In Example 1, evaluation is performed on three recesses R1, R2, and R3 with different critical dimension (CD) sizes. The same conditions are set for both of the cases where the boron adsorption layer 140 is formed and is not formed, except for the presence or absence of the boron adsorption layer 140. In Example 1, the temperature of the substrate 100 is set to 200 degrees C. when forming the boron adsorption layer 140 and is set to 450 degrees C. when forming the titanium silicide film 150.

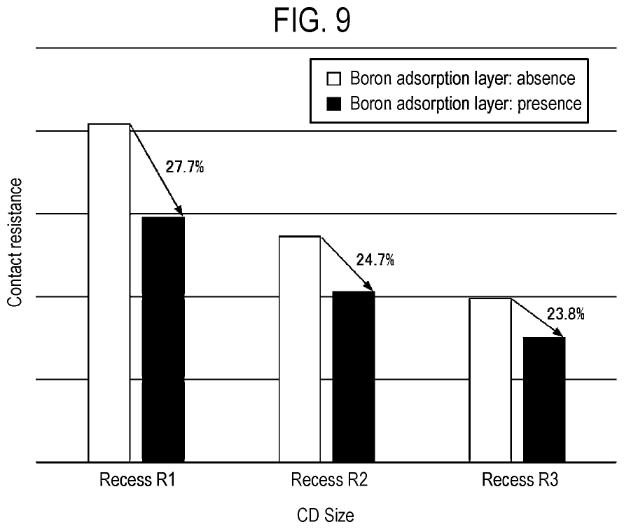

FIG. 9 is a diagram illustrating measurement results of the contact resistance in Example 1. The bar graphs on the left, center, and right in FIG. 9 respectively show comparison results of contact resistance for the recesses R1, R2, and R3, for cases where the boron adsorption layer 140 is formed on the doped region 121 (black bars) and cases where the boron adsorption layer 140 is not formed (white bars).

As illustrated in FIG. 9, it is seen that in the recess R1, the contact resistance when the boron adsorption layer 140 is formed on the doped region 121 is 27.7% lower than the contact resistance when the boron adsorption layer 140 is not formed on the doped region 121. It is seen that in the recess R2, the contact resistance when the boron adsorption layer 140 is formed on the doped region 121 is 24.7% lower than the contact resistance when the boron adsorption layer 140 is not formed on the doped region 121. It is seen that in the recess R3, the contact resistance when the boron adsorption layer 140 is formed on the doped region 121 is 23.8% lower than the contact resistance when the boron adsorption layer 140 is not formed on the doped region 121. It is found from these results that forming the boron adsorption layer 140 on the doped region 121 before forming the titanium silicide film 150 on the doped region 121 may achieve a low contact resistance.

### Example 2

In Example 2, instead of forming the titanium silicide film 150 on the doped region 121, a molybdenum silicide film is formed on the doped region 121. In Example 2, a contact resistance between the doped region 121 and the molybdenum silicide film is compared for cases where the boron adsorption layer 140 is formed and is not formed on the doped region 121, before forming the molybdenum silicide film on the doped region 121. In Example 2, evaluation is performed on three recesses R1, R2, and R3 with different critical dimension (CD) sizes. The same conditions are set for both of the cases where the boron adsorption layer 140 is formed and is not formed, except for the presence or absence of the boron adsorption layer 140. In Example 2, the temperature of the substrate 100 is set to 300 degrees C. when forming the boron adsorption layer 140 and is set to 400 degrees C. when forming the molybdenum silicide film. In addition, molybdenum pentachloride gas is used as a molybdenum-containing gas when forming the molybdenum silicide film.

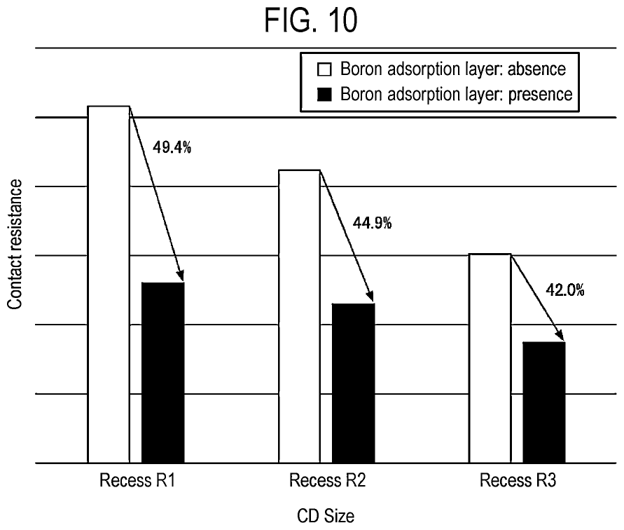

FIG. 10 is a diagram illustrating measurement results of the contact resistance in Example 2. The bar graphs on the left, center, and right in FIG. 10 respectively show comparison results of contact resistance for the recesses R1, R2, and R3, for cases where the boron adsorption layer 140 is formed on the doped region 121 (black bars) and cases where the boron adsorption layer 140 is not formed (white bars).

As illustrated in FIG. 10, it is seen that in the recess R1, the contact resistance when the boron adsorption layer 140 is formed on the doped region 121 is 49.4% lower than the contact resistance when the boron adsorption layer 140 is not formed on the doped region 121. It is seen that in the recess R2, the contact resistance when the boron adsorption layer 140 is formed on the doped region 121 is 44.9% lower than the contact resistance when the boron adsorption layer 140 is not formed on the doped region 121. It is seen that in the recess R3, the contact resistance when the boron adsorption layer 140 is formed on the doped region 121 is 42.0% lower than the contact resistance when the boron adsorption layer 140 is not formed on the doped region 121. It is found from these results that forming the boron adsorption layer 140 on the doped region 121 before forming the molybdenum silicide film on the doped region 121 may achieve a low contact resistance.

The embodiment disclosed herein should be considered illustrative in all respects and not restrictive. The above-described embodiment may be omitted, replaced, or changed in various forms without departing from the scope of the appended claims and their spirit.

In the above-described embodiment, a case where an impurity is boron and an impurity-containing gas is a diborane gas has been described, but the present disclosure is not limited to this. For example, the impurity-containing gas may be another boron-containing gas such as boron trichloride (BCl₃) gas. For example, the impurity may be a p-type impurity other than boron, and the impurity-containing gas may be a gas containing the p-type impurity. For example, the impurity may be phosphorus (P), and the impurity-containing gas may be a phosphorus-containing gas such as a phosphine (PH₃) gas. For example, the impurity may be an n-type impurity other than phosphorus, and the impurity-containing gas may be a gas containing the n-type impurity.

In the above-described embodiment, a case where the first metal-containing gas is a titanium tetrachloride gas has been described, but the present disclosure is not limited to this. For example, the first metal-containing gas may be another titanium-containing gas such as titanium bromide (TiBr₄) gas, tetrakis(dimethylamino) titanium (TDMAT) gas, tetrakis(diethylamino) titanium (TDEAT) gas, etc. Also, for example, the first metal-containing gas may be a molybdenum-containing gas. The molybdenum-containing gas may be a molybdenum halide gas, a molybdenum oxyhalide gas, etc. The halogen is fluorine, chlorine, bromine, or iodine. Further, for example, the first metal-containing gas may be a metal-containing gas that contains at least one selected from the group of titanium, nickel (Ni), cobalt (Co), platinum (Pt), molybdenum (Mo), tantalum (Ta), hafnium (Hf), zirconium (Zr), ruthenium (Ru), niobium (Nb), antimony (Sb), and bismuth (Bi).

In the above-described embodiment, a case where the second metal-containing gas is the same gas as the first metal-containing gas has been described, but the present disclosure is not limited to this. For example, the second metal-containing gas may be a different gas from the first metal-containing gas. For example, the second metal-containing gas may be any of the metal-containing gases exemplified as the first metal-containing gas.

In the above-described embodiment, a case where a metal constituting a metal film is titanium has been described, but the present disclosure is not limited to this. For example, the metal constituting the metal film may be at least one metal selected from the group of titanium, nickel, cobalt, platinum, molybdenum, tantalum, hafnium, zirconium, ruthenium, niobium, antimony, and bismuth.

According to the present disclosure in some embodiments, it is possible to prevent the diffusion of an impurity from a substrate to a metal silicide film.

While certain embodiments have been described, these embodiments have been presented by way of example only, and are not intended to limit the scope of the disclosures. Indeed, the embodiments described herein may be embodied in a variety of other forms. Furthermore, various omissions, substitutions and changes in the form of the embodiments described herein may be made without departing from the spirit of the disclosures. The accompanying claims and their equivalents are intended to cover such forms or modifications as would fall within the scope and spirit of the disclosures.

What is claimed is:

1. A film forming method comprising:
(a) preparing a substrate having a doped region, which contains silicon with an added impurity, formed on a surface;
(b) forming a diffusion prevention layer, which contains the impurity, on the doped region; and
(c) forming a metal film on the doped region where the diffusion prevention layer is formed, and forming a metal silicide film by a reaction between the metal film and the silicon of the doped region,
wherein (b) includes supplying an impurity-containing gas that contains the impurity to the substrate without converting the impurity-containing gas into a plasma.

2. The film forming method of claim 1, wherein (b) is performed in a state where a metal-containing gas is not supplied to the substrate.

3. The film forming method of claim 2, wherein (b) includes continuously supplying the impurity-containing gas to the substrate.

4. The film forming method of claim 2, wherein (b) includes intermittently supplying the impurity-containing gas to the substrate.

5. The film forming method of claim 2, wherein (b) includes maintaining the substrate at a temperature lower than a temperature at which the impurity-containing gas self-decomposes.

6. The film forming method of claim 1, wherein (b) includes supplying a first metal-containing gas to the substrate.

7. The film forming method of claim 6, wherein (b) includes simultaneously performing the supplying the impurity-containing gas to the substrate without converting the impurity-containing gas into a plasma and the supplying the first metal-containing gas to the substrate.

8. The film forming method of claim 6, wherein (b) includes alternately repeating the supplying the impurity-containing gas to the substrate without converting the impurity-containing gas into a plasma and the supplying the first metal-containing gas to the substrate.

9. The film forming method of claim 8, wherein the supplying the impurity-containing gas to the substrate without converting the impurity-containing gas into a plasma is performed first.

10. The film forming method of claim 6, wherein the first metal-containing gas is supplied to the substrate without converting the first metal-containing gas into a plasma.

11. The film forming method of claim 6, wherein (c) includes supplying a second metal-containing gas to the substrate, and the second metal-containing gas is a same gas as the first metal-containing gas.

12. The film forming method of claim 6, wherein the first metal-containing gas contains at least one metal selected from the group of titanium (Ti), nickel (Ni), cobalt (Co), platinum (Pt), molybdenum (Mo), tantalum (Ta), hafnium (Hf), zirconium (Zr), ruthenium (Ru), niobium (Nb), antimony (Sb), and bismuth (Bi).

13. The film forming method of claim 6, wherein the first metal-containing gas is a titanium tetrachloride gas or a molybdenum pentachloride gas.

14. The film forming method of claim 1, wherein the supplying the impurity-containing gas to the substrate without converting the impurity-containing gas into a plasma in (b) is performed in a state where a metal-containing gas is not supplied to the substrate, and
wherein (b) includes alternately repeating the supplying the impurity-containing gas to the substrate without converting the impurity-containing gas into a plasma and supplying a first metal-containing gas to the substrate.

15. The film forming method of claim 1, wherein the supplying the impurity-containing gas to the substrate without converting the impurity-containing gas into a plasma in (b) is performed in a state where a metal-containing gas is not supplied to the substrate, and
wherein (b) includes simultaneously performing the supplying the impurity-containing gas to the substrate without converting the impurity-containing gas into a plasma and supplying a first metal-containing gas to the substrate.

16. The film forming method of claim 1, wherein the impurity is a p-type impurity.

17. The film forming method of claim 16, wherein the p-type impurity is boron.

18. The film forming method of claim 1, wherein the impurity is an n-type impurity.

19. The film forming method of claim 18, wherein the n-type impurity is phosphorus.

20. The film forming method of claim 1, wherein the impurity-containing gas is a diborane gas.

21. The film forming method of claim 1, wherein the impurity-containing gas is phosphine.

22. The film forming method of claim 1, wherein the metal silicide film is a titanium silicide film or a molybdenum silicide film.

23. The film forming method of claim 1, wherein (c) is performed at a higher temperature than (b).

24. The film forming method of claim 1, further comprising:
(d) removing a native oxide film on a surface of the doped region before (b).

25. The film forming method of claim 24, wherein (d) includes supplying a gas containing a halogen element and a basic gas as process gases to the substrate.

26. A processing system comprising:
a processing container configured to accommodate a substrate having a doped region, which contains silicon with an added impurity, formed on a surface;
a supplier configured to supply a gas to the substrate accommodated in the processing container; and
a controller,
wherein the controller is configured to control the supplier to execute a process including:
forming a diffusion prevention layer, which contains the impurity, on the doped region;
forming a metal film on the doped region where the diffusion prevention layer is formed, and forming a metal silicide film by a reaction between the metal film and the silicon of the doped region, and
wherein the forming the diffusion prevention layer includes supplying an impurity-containing gas that contains the impurity to the substrate without converting the impurity-containing gas into a plasma.
